(19) United States
(12) Patent Application Publication
(10) Pub. No.: US 2026/0153565 A1
(43) Pub. Date: Jun. 4, 2026

(54) DETERMINING CAPACITY INDICATORS FOR BATTERY CELL GROUPS

(71) Applicants: VOLKSWAGEN AKTIENGESELLSCHAFT, WOLFSBURG (DE); The Board of Trustees of the Leland Stanford Junior University, Stanford, CA (US)

(72) Inventors: Andrea Lanubile, Menlo Park, CA (US); Pietro Bosoni, Menlo Park, CA (US); Gabriele Pozzato, Palo Alto, CA (US); William Paxton, Redwood City, CA (US); Simona Onori, Palo Alto, CA (US)

(21) Appl. No.: 18/969,146

(22) Filed: Dec. 4, 2024

(51) Int. Cl. G01R 31/388; B60L 58/22; G01R 31/36; G01R 31/367; H02J 7/00

(52) U.S. Cl. CPC G01R 31/388; B60L 58/22; G01R 31/3646; G01R 31/367; H02J 7/56; H02J 7/82; H02J 7/96

(57) ABSTRACT

A method of determine a capacity indicator for a battery cell group is provided. The method includes determining a missing capacity for a battery cell group during a charging event. The missing capacity indicates a difference between a first amount of energy stored at a full capacity of the battery cell group and a second amount of stored at a current capacity of the battery cell group. The method also includes determining a voltage of the battery cell group during the charging event. The method further includes determining a capacity indicator of the battery cell group based on whether balancing was performed based on one or more of the missing capacity and the voltage.

### TECHNICAL FIELD

Aspects of the present disclosure relate to a battery management system for determining capacity indicators, and more particularly, to a battery management system for determining capacity indicators for battery cell groups.

### BACKGROUND

Various devices (e.g., smart phones, computing devices, laptop computers, tablet computers, etc.) and apparatuses (e.g., vehicles) may use a power source to operate. For example, a vehicle may use a battery, fuel, a fuel cell, or some other power source to power the components of the vehicle and/or to move the vehicle. As the battery is discharged (to provide power to the vehicle) and charged, the battery may age. As the battery ages, the performance of the battery may degrade. For example, the battery may require more voltage/current to charge, the capacity (e.g., the total power/storage capacity) of the battery may decrease, and/or the amount of power provided by the battery may decrease.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 is a block diagram that illustrates an example vehicle, in accordance with one or more embodiments of the present disclosure.

FIG. 2 is a diagram illustrating an example battery management system, in accordance with one or more embodiments of the present disclosure.

FIG. 3 is a block diagram that illustrates an example system architecture, in accordance with some embodiments of the present disclosure.

FIG. 4 is a diagram that illustrates an example battery module, in accordance with some embodiments of the present disclosure.

FIG. 5 is a diagram illustrating example battery cell groups, in accordance with one or more embodiments of the present disclosure.

FIG. 6 is a flow diagram of a method for determining a capacity indicator, in accordance with one or more embodiments of the present disclosure.

FIG. 7 is a block diagram of an example computing device that may perform one or more of the operations described herein, in accordance with some embodiments of the present disclosure.

### DETAILED DESCRIPTION

As discussed above, when a power source, such as a battery, is discharged (to provide power to a device/apparatus, such as a vehicle) and charged, the battery may age. As the battery ages, the battery may require more voltage/current to charge, the capacity (e.g., the total storage capacity) of the battery may decrease, and/or the amount of power provided by the battery may decrease. The health of the battery (e.g., a state of health) may be an indicator to quantify an aging level for a battery in terms of changes in capacity (e.g., a decrease in capacity) and/or changes in internal resistance (e.g., increase in resistance). Determining the health of the battery may be useful and/or important for improving battery life, understanding battery operation, and gaining increased performance from the battery.

While the health of a battery may be measured with sufficient accuracy from lab tests, it is difficult to determine the health of a battery while the battery is in use (e.g., while the battery is installed in a device, such as a vehicle). For example, it may be difficult to determine the health of the battery while the battery is being charged and/or discharged (e.g., when power from the battery is used to drive a vehicle, power electronics, etc.). Because it is difficult to determine the health of the battery while the battery is in use (e.g., is charging/discharging), it may be difficult to determine the health of the battery and/or changes to the health of the battery that occur after a battery has been charged (e.g., after a charging event).

As discussed above, a battery may be constantly charged and discharged. During charging, the amount of stored energy in different battery cell groups may not be uniform. For example, due to various factors such as temperature, manufacturing variations, etc., the amount of energy stored in different battery cell groups may vary (e.g., may not be even, may not be uniformly distributed, may not be evenly distributed, etc.) after a charging event. For example, after a charging event, some battery cell groups may have less energy than other battery cell groups. This may make it difficult for a general battery management system to determine the capacity of the battery and/or to determine a health (e.g., an amount of degradation or aging) of the battery.

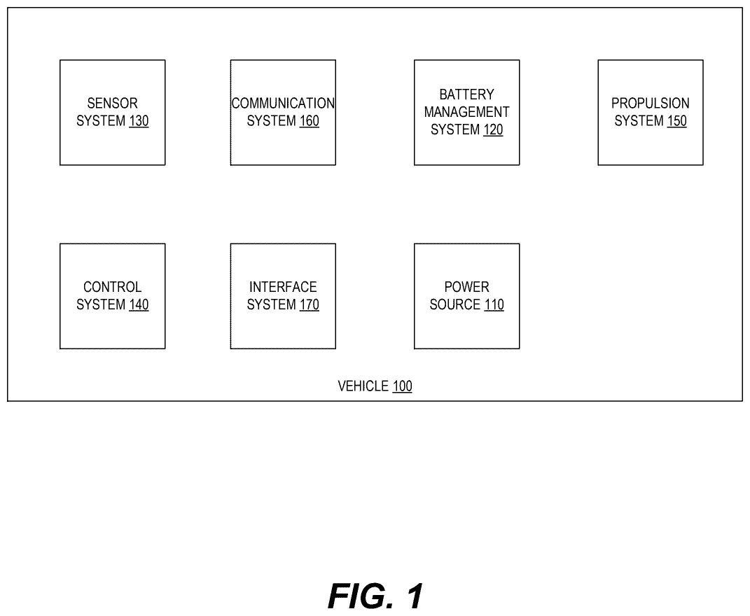

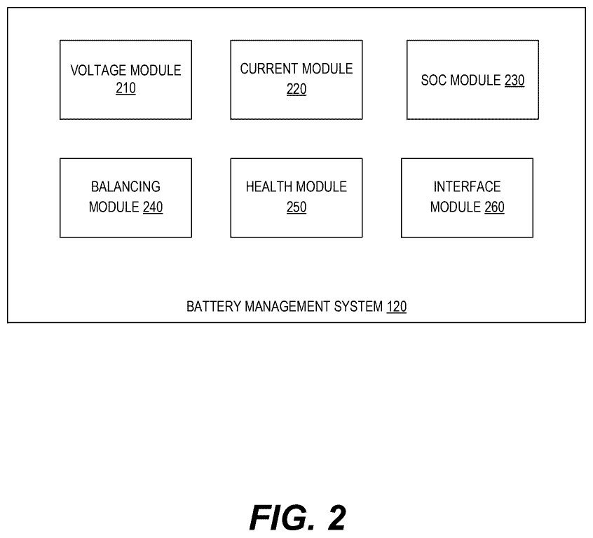

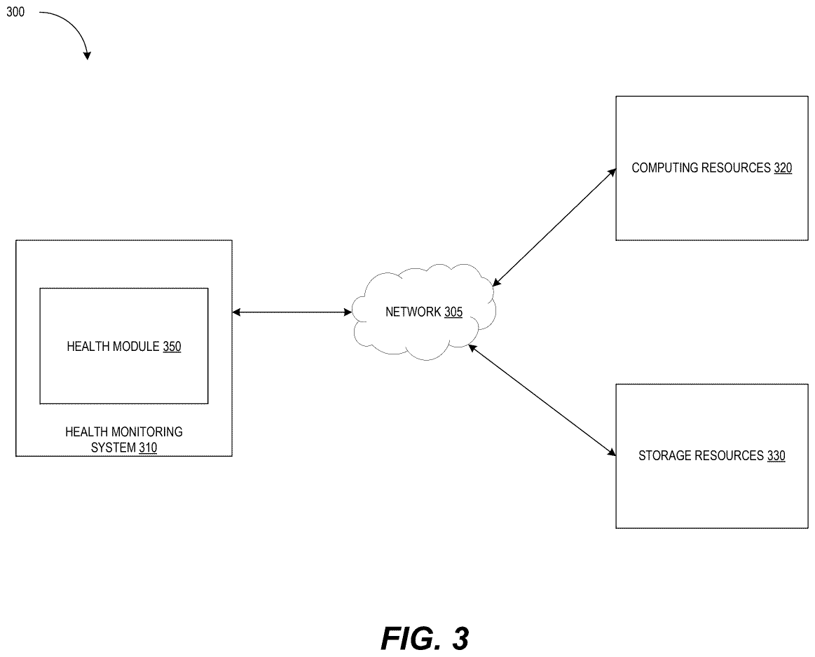

The embodiments, implementations, and/or examples, described herein may allow a health module (e.g., health module 250 illustrated in FIGS. 2-3) and/or a battery management system (e.g., the battery management system 120 illustrated in FIGS. 1-2) to determine a capacity indicator for each battery cell group in a battery (e.g., in a power source). The capacity indicator may be value that indicates storage capacity (or a range of storage capacities) for the battery cell group. For example, a higher value may indicate that the battery cell group has a higher capacity and a lower value may indicate that the battery cell group has a lower capacity. This may allow the battery management system to more accurately measure the capacity of the battery and to provide a more accurate indication of the health of the battery.

Although the present disclosure may refer to batteries (e.g., lithium-ion batteries or batteries using other battery chemistries) and vehicles, the examples, implementations, aspects, and/or embodiments described herein may be used with various types of power sources for various types of devices/apparatuses.

FIG. 1 is a block diagram that illustrates an example vehicle 100, in accordance with one or more embodiments of the present disclosure. In one embodiment, the vehicle 100 may be an autonomous vehicle (e.g., a self-driving vehicle). For example, the vehicle 100 may be a vehicle (e.g., car, truck, van, mini-van, semi-truck, taxi, drone, etc.) that may be capable of operating autonomously or semi-autonomously. In another embodiment, the vehicle 100 may also be a vehicle with autonomous capabilities. A vehicle with autonomous capabilities may be a vehicle that may be capable of performing some operations, actions, functions, etc., autonomously. For example, vehicle 100 may have adaptive cruise control capabilities and/or lane assist/keep capabilities. A vehicle 100 with autonomous capabilities may be referred to as a semi-autonomous vehicle.

The vehicle 100 may include various systems that allow the vehicle 100 to operate specific functions. For example, vehicle 100 includes a sensor system 130, a control system 140, a communication system 160, an interface system 170, a propulsion system 150, a power source 110, and a battery management system 120. In other embodiments, the vehicle 100 may include more, fewer, and/or different systems, and each system may include more, fewer, and/or different components. Additionally, the systems and/or components may be combined and/or divided in any number/possibility of arrangements.

The sensor system 130 may include one or more sensors (e.g., detectors, sensing elements, sensor devices, etc.). The one or more sensors may provide information about the operation of the vehicle 100, information about the condition of the vehicle 100, information about occupants/users of the vehicle 100, and/or information about the environment (e.g., a geographical area) where the vehicle 100 is located. The one or more sensors may be coupled to various types of communication interfaces (e.g., wired interfaces, wireless interfaces, etc.) to provide sensor data to other systems of the vehicle 100. For example, a sensor may be coupled to a storage device (e.g., a memory, a cache, a buffer, a disk drive, flash memory, etc.) and/or a computing device (e.g., a processor, an ASIC, an FPGA, etc.) via a control area network (CAN) bus (or other type of communication bus, such as a Flexray). In another example, a sensor may be coupled to a storage drive and/or a computing device via Bluetooth, Wi-Fi, etc. Examples of sensors may include, but are not limited to, tire pressure sensors, steering sensors (e.g., to determine the positions/angles of one or more wheels), a compass, temperature sensors, a global positioning system (GPS) receiver/sensor, a light detection and ranging (LIDAR) device/sensor, an ultrasonic device/sensor, a camera (e.g., a video camera), a radar device/sensor, etc.

The control system 140 may include hardware, software, firmware, or a combination thereof that may control the functions, operations, actions, etc., of the vehicle 100. For example, the control system 140 may be able to control a braking system and/or an engine to control the speed and/or acceleration of the vehicle 100. In another example, the control system 140 may be able to control a steering system to turn the vehicle 100 left or right. In a further example, the control system 140 may be able to control the headlights or an all-wheel drive (AWD) system of the vehicle 100 based on weather/driving conditions (e.g., if the environment has snow/rain, if it is nighttime in the environment, etc.). The control system 140 may use sensor data and/or outputs generated by machine learning models to control the vehicle 100.

The control system 140 may use outputs generated one or more machine learning models to control the vehicle. For example, control system 140 may generate one or more steering commands based on the outputs of a machine learning model (e.g., based on objects detected by a machine learning model). The steering command may indicate the direction that a vehicle 100 should be turned (e.g., left, right, etc.) and may indicate the angle of the turn. The control system 140 may actuate one or more mechanisms/systems (e.g., a steering system, a steering wheel, etc.) to turn the vehicle 100 (e.g., to control the vehicle 100) based on the steering command. For example, the control system 140 may actuate one or more steering mechanisms that may turn/move the wheels of the vehicle by a certain number of degrees to steer the vehicle 100. The control system 140 may also control acceleration and/or deceleration of the vehicle 100. For example, the control system 140 may use the accelerator to speed up the vehicle 100 or may use the brake to slow down the vehicle 100.

The communication system 160 may include various devices, systems, components, software, hardware, firmware, etc., that allow the vehicle 100 to communicate (e.g., transmit and/or receive data) with various networks (e.g., computer networks, communication networks, etc.) and/or devices (e.g., other vehicles, server computers, etc.). For example, the communication system 160 may include antennas, network interfaces, wireless network interfaces (e.g., cellular, Wi-Fi, Bluetooth, ZigBee, ZWave, and/or other network interfaces). The communication system 160 may also allow the vehicle 100 to communicate with other vehicles (e.g., V2V communications), with infrastructure (e.g., V2I communications), and/or with other devices/networks (e.g., V2X communications).

The interface system 170 may include various devices, systems, components, software, hardware, firmware, etc., that allow the vehicle 100 to interact with external sensors, other vehicles, external computing devices, and/or a user. For example, the interface system 170 may include buttons, knobs, dials, touch screens, microphones, cameras, and/or other devices that interact with a user, present information to a user, receive user input from a user, etc. The interface system 170 may be used to display and/or indicate a health (e.g., a state of health, SoH, etc.) of the power source 110, as discussed in more detail below.

The propulsion system 150 may include various devices, systems, components, software, hardware, firmware, etc., that may be used to move the vehicle 100. For example, the propulsion system 150 may include an engine/motor, an energy source, a transmission, and wheels/tires. The engine/motor may include any combination of an internal combustion engine, an electric motor (that can be powered by an electrical battery, fuel cell, and/or other energy storage device), and/or a steam engine.

The power source 110 may be a source of energy that provides power (e.g., energy, electricity, etc.) to various components, modules, and/or systems of the vehicle 100. For example, the power source 110 may be used to power one or more of the sensor system 130, control system 140, communication system 160, interface system 170, propulsion system 150. Examples of power sources (e.g., energy sources) may include gasoline, diesel, propane, other compressed gas-based fuels, ethanol, solar panels, batteries, and other sources of electrical power. The power source 110 may be a combination of multiple power sources (e.g., may include any combination of fuel tanks, batteries, capacitors, and/or flywheels). In one embodiment, the power source 110 may be a battery (e.g., a lithium-ion battery, an electrical battery, etc.).

The battery management system (BMS) 120 may include various devices, systems, components, software, hardware, firmware, etc., that may monitor (e.g., detect, measure, etc.) the various characteristics of the power source 110. For example, if the power source 110 is a battery, the BMS 120 may monitor characteristics (e.g., operating parameters, conditions, etc.) such as battery temperature, battery voltage, battery current, battery charging and discharging data, state of charge of the power source 110, etc. The characteristics can be stored locally in the vehicle 100 by the BMS 120. The BMS 120 can also transmit such monitored information via the communication system 160 to other devices (e.g., to a server computer, to a cloud, etc.). The BMS 120 may also regulate the operating conditions of the power source 110. For example, the BMS 120 may cool the battery temperature to within a predefined threshold temperature. The BMS 120 may further manage, regulate, control, etc., the operation and/or usage of the power source 110, as discussed in more detail below.

Although not illustrated in FIG. 1, the vehicle 100 may also include various computing resources and/or devices. For example, the vehicle 100 may include hardware such as processing devices (e.g., processors, central processing units (CPUs), processing cores, graphics processing units (GPUS)), memory (e.g., random access memory (RAM), storage devices (e.g., hard-disk drive (HDD), solid-state drive (SSD), etc.), and other hardware devices (e.g., sound card, video card, etc.). The vehicle 100 may also include computing devices. The computing devices may comprise any suitable type of computing device or machine that has a programmable processor including, for example, a computer. In some examples, the computing devices may include a single machine or may include multiple interconnected machines (e.g., multiple computers configured in a cluster).

Some of the embodiments described herein use the states of charge (e.g., a percentage or amount of energy in a power source, such as a battery), various storage capacities (e.g., a current capacity, a maximum capacity, etc.), and current/voltage provided to a battery (e.g., the amount of current/voltage provided to the battery to charge the battery) during charging events to determine capacity indicators. These currents, voltages, and/or states of charge may be measured and/or determined during the charging event, which allows for a battery management system to perform balancing on battery cell groups within a battery. Based on the balancing that is performed on the battery cell groups, a health module may be able to determine/calculate the capacity indicators.

As discussed above, after a charging event, the amount of stored energy in different battery cell groups of a battery may not be the same. For example, some battery cell groups may have more energy than other battery cell groups. This may make it difficult for a general battery management system to determine the capacity of the battery and/or to determine a health (e.g., an amount of degradation or aging) of the battery.

The embodiments, implementations, and/or examples, described herein may allow the battery management system 120 to determine a capacity indicator for each battery cell group in power source 110 (e.g., a battery). The capacity indicator may indicate the storage capacity (or a range of storage capacities) for a particular battery cell group. By determining a capacity indicator for each group, the battery management system 120 may be able to more accurately measure the capacity of the power source 110. In addition, the capacity indicator may also allow the battery management system 120 to provide a more accurate indication of the health of the power source 110 (e.g., a more accurate indication of the amount of degradation or capacity loss in the power source 110).

FIG. 2 is a block diagram that illustrates an example battery management system 120, in accordance with one or more embodiments of the present disclosure. The battery management system 120 includes a voltage module 210, a current module 220, a state of charge (SOC) module 230, a balancing module 240, a health module 250, and an interface module 260. Some or all of the modules, components, systems, engines, etc., illustrated in FIG. 2 may be implemented in software, hardware, firmware, or a combination thereof. The battery management system 120 may be part of a vehicle (e.g., vehicle 100 illustrated in FIG. 1). The battery management system 120 may monitor various characteristics of a power source used by the vehicle and/or may manage (e.g., control) the operation/usage of the power source 110 illustrated in FIG. 1.

In one embodiment, the current module 220 may determine (e.g., detect, measure, test, etc.) the amount of current that is flowing via/through the power source. For example, the current module 220 may detect/measure the amount of current that is provided to the power source (e.g., a battery). In another example, the current module 220 may detect/measure the amount of current that is drawn from the power source (e.g., the amount of current that the power source provides to a load, such as an electric motor or other component/device that uses power). The current module 220 may use one or more sensors/devices (e.g., current meters/detectors, a current probe, an ammeter, etc.) to measure the amount of current as that is provided to and/or drawn from the power source. For example, the current module 220 may use a current meter to determine the amount of current that is provided to the power source while the power source is being charged (e.g., while the power source is charged using regenerative braking or via a power plug, during a charging event, etc.). In another example, the current module 220 may use a current meter to determine the amount of current that drawn from the power source (e.g., discharged from the battery) while the vehicle is using the battery (e.g., while the vehicle is drawing power from the battery to accelerate/move the vehicle). In some embodiments, the current module 220 may determine the amount of current that is provided/flows to individual battery cells groups in a power source (e.g., battery cell groups in a battery).

In one embodiment, the voltage module 210 may also determine the voltage of a current that is provided to the power source. For example, the power source (e.g., the battery) may be charged by the current provided to the power source during charging (e.g., during a charging event). The voltage module 210 may use one or more sensors/devices (e.g., voltage meters/detectors) to measure the voltage of the current as the power source is charged (e.g., charged via a power cable/connector) and/or discharged. The current that is provided to the power source and/or drawn from the power source may be represented using the following equation:

$$I = V / R \qquad ( 1 )$$

where I is the current, V is the voltage component of the current (e.g., voltage of the current), and R is the resistance component of the current (e.g., resistance). As described herein, the voltage of the current may refer to the voltage component of the current (e.g., V in equation (1)). In some embodiments, the current module 220 may determine voltages for individual battery cells groups in a power source (e.g., battery cell groups in a battery).

In one embodiment, the SOC module 230 may determine the state of charge of the power source (e.g., a battery) of the vehicle. For example, the SOC module 230 may determine/measure how much power the battery is capable of providing at various points in time. In another example, the SOC module 230 may determine the amount of power remaining in the battery. The state of charge of the battery may be represented in various ways. For example, the state of charge may be represented using a number or percentage, where 0 (or some other appropriate minimum number) may be the lowest state of charge and 100 (or some other appropriate maximum number) may be the highest state of charge. In another example, the state of charge may be represented by the remaining power/energy in the battery in terms of watt hours, kilowatt hours, etc. The state of charge of the power source may be referred to as the SoC, SOC, etc. In some embodiments, the current module 220 may determine the state of charge for individual battery cells groups in a power source (e.g., battery cell groups in a battery).

In one embodiment, the SOC module 230 may determine the state of charge of the power source at the beginning of a charging event and an end of the charging event. For example, the SOC module may determine a starting time (e.g., a start time, a first time, etc.) when the charging event started (e.g., when a power supply, such as a charger plug, was connected to the power source, when power/energy starting flowing to the power source, etc.) and may determine the state of charge of the power source when the charging event started (e.g., a starting state of charge). The SOC module 230 may also determine an ending time (e.g., an end time, a second time, etc.) when the charging event ended (e.g., when a power supply, such as a charger plug, was disconnected from the power source, when power/energy stopped flowing to the power source, etc.) and may determine the state of charge of the power source when the charging event ended (e.g., an ending state of charge).

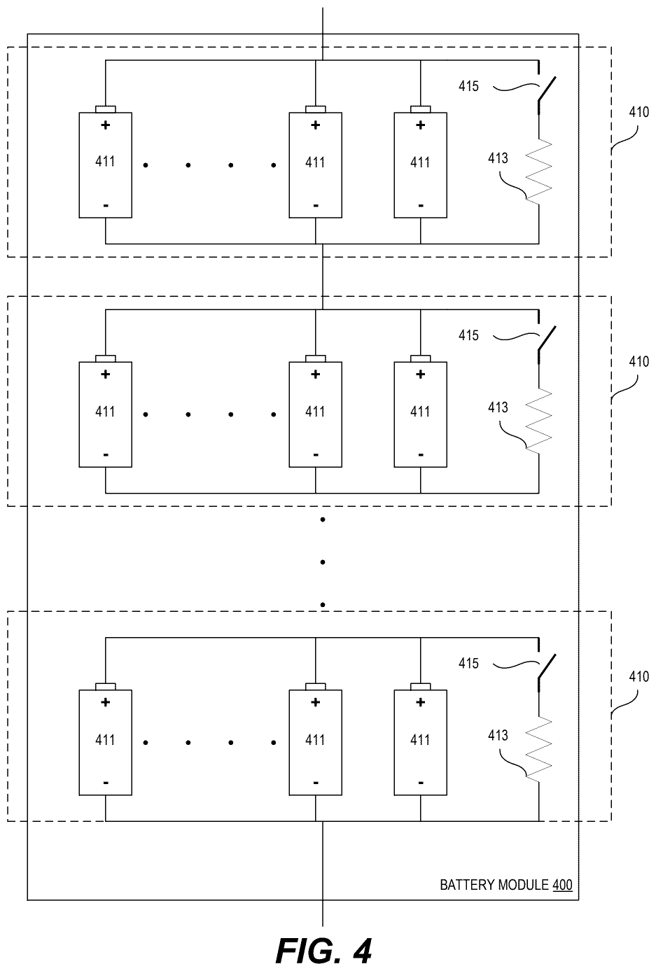

In one embodiment, the balancing module 240 may perform balancing operations on one or more battery cell groups of a battery (e.g., a power source). As illustrated below in FIG. 4, a battery may include multiple battery modules and each battery module may include multiple battery cells groups. As the battery is charged and/or discharged, the amount of energy stored in the different battery cell groups may be different (e.g., due to manufacturing variations, temperature difference, etc.). The balancing module 240 may perform balancing operations to evenly distribute the current/power received from a power supply to the different battery cell groups. This may allow the balancing module 240 to help prevent damage to the battery cell groups (e.g., to prevent overcharging of particular battery cell groups). Balancing operations may be performed based on various parameters, criterion, conditions, etc. For example, balancing operations may be performed on a battery cell group based on the voltage of the battery cell group, the missing capacity in a battery cell group, etc. Balancing operations and battery cell groups are discussed in more detail below.

In one embodiment, the health module 250 may determine one or more capacity indicators for one or more battery cell groups of a power source (e.g., a battery). The health module 250 may determine the one or more capacity indicators based on balancing operations that were performed. For example, the health module 250 may determine a capacity indicator for a battery cell group based on how the balancing operations are performed (e.g., triggered), as discussed in more detail below.

In one embodiment, the capacity indicator may be an indication of the amount of degradation in the capacity (e.g., storage capacity) of the power source (e.g., the battery) and/or portions of the power source (e.g., a battery cell group, a battery module that includes multiple battery cell groups). For example, a lower capacity indicator may indicate more/higher degradation in the capacity of the power source, or vice versa. The range of values for the capacity indicator may be any appropriate range. For example, three values may be used for the capacity indicator, with one value indicate a low degradation in capacity, a second value indicating a medium degradation in capacity, a third value indicating a high degradation in capacity. In another example, ten values may be used for the capacity indicator. In a further example, four values may be used for the capacity indicator.

In one embodiment, the health module 250 may use a machine learning model to determine a capacity indicator for a battery cell group. Information about the balancing operations (e.g., whether balancing operations were performed, and how often and/or how long balancing operations were formed for a particular battery cell group) may be provided to the machine learning model. Based on the information about the balancing operations, the machine learning model may be able to determine, generate, calculate, etc., a capacity indicator for a battery cell group.

In one embodiment, the health module 250 may determine a combined or aggregate capacity indicator based on multiple capacity indicators. For example, the health module 250 may obtain an average, weighted average, or may use some other function/operation to obtain the combined/aggregate capacity indicator. The combined or aggregate capacity indicator may be for a battery module (which may include multiple battery cell groups) and/or may be for the entire battery.

In one embodiment, the functions, formulas, correlations, etc., between the capacity indicators and the amount of degradation in the capacity of a power source or portion of a power source (e.g., a battery cell group) may be determined based on experimentation and/or testing with different types of power sources (e.g., different battery packs with different chemistries). For example, a previous battery (e.g., battery pack) may have been charged and discharged, and capacity indicators may have been calculated/determined based on previous charging events for the previous battery. The capacity indicators (for different states of charge) at different ages of the previous battery may be recorded in table, list, or some other appropriate data structure. The capacity indicators for the previous battery may be referred to as reference capacity indicators. The health module 250 may use the reference capacity indicators to determine the health of the power source based on the capacity indicators obtained while the power source is charging (e.g., during a charging event). Different sets of reference capacity indicators may be determined for different types of battery packs. For example, a set of reference capacity indicators may be determined for each configuration/combination of cells, battery chemistries, capacities, etc., for a battery pack.

In one embodiment, the interface module 260 may provide an indication of the capacity indicator (of different portions of a battery, such as battery cell groups, and/or of the entire battery) to an interface system (e.g., interface system 170 illustrated in FIG. 1). For example, the interface module 260 may transmit a message indicating or more capacity indicators for one or more power cell groups to the interface module 260. The interface module 260 may display the one or more capacity indicators (or icons, images, text, etc., representing the capacity indicators) and/or other information/data to a user (e.g., via one or more screens, displays, touch screens, etc.). The interface system may also receive user input (e.g., via buttons, touchscreens, etc.) that may allow the user to control the operation of the vehicle.

FIG. 3 is a block diagram that illustrates an example system architecture 300, in accordance with some embodiments of the present disclosure. The system architecture 300 includes network 305, a health monitoring system 310, computing resources 320, and storage resources 330. Network 305 may interconnect the health monitoring system 310, the computing resources 320, and/or the storage resources 330. Network 305 may be a public network (e.g., the internet), a private network (e.g., a local area network (LAN) or wide area network (WAN)), or a combination thereof. In one embodiment, network 305 may include a wired or a wireless infrastructure, which may be provided by one or more wireless communications systems, such as a wireless fidelity (Wi-Fi) hotspot connected with the network, a cellular system, and/or a wireless carrier system that can be implemented using various data processing equipment, communication towers (e.g. cell towers), etc. Network 305 may carry communications (e.g., data, message, packets, frames, etc.) between the health monitoring system 310, the computing resources 320 and/or the storage resources 330.

The computing resources 320 may include computing devices which may include hardware such as processing devices (e.g., processors, central processing units (CPUs), processing cores, graphics processing units (GPUS)), memory (e.g., random access memory (RAM), storage devices (e.g., hard-disk drive (HDD), solid-state drive (SSD), etc.), and other hardware devices (e.g., sound card, video card, etc.). The computing devices may comprise any suitable type of computing device or machine that has a programmable processor including, for example, server computers, desktop computers, rackmount servers, etc. In some examples, the computing devices may include a single machine or may include multiple interconnected machines (e.g., multiple servers configured in a cluster, cloud computing resources, etc.).

The computing resources 320 may also include virtual environments. In one embodiment, a virtual environment may be a virtual machine (VM) that may execute on a hypervisor which executes on top of the OS for a computing device. The hypervisor may also be referred to as a virtual machine monitor (VMM). A VM may be a software implementation of a machine (e.g., a software implementation of a computing device) that includes its own operating system (referred to as a guest OS) and executes application programs, applications, software. The hypervisor may be a component of an OS for a computing device, may run on top of the OS for a computing device, or may run directly on host hardware without the use of an OS. The hypervisor may manage system resources, including access to hardware devices such as physical processing devices (e.g., processors, CPUs, etc.), physical memory (e.g., RAM), storage device (e.g., HDDs, SSDs), and/or other devices (e.g., sound cards, video cards, etc.). The hypervisor may also emulate the hardware (or other physical resources) which may be used by the VMs to execute software/applications. The hypervisor may present other software (i.e., “guest” software) the abstraction of one or more virtual machines (VMs) that provide the same or different abstractions to various guest software (e.g., guest operating system, guest applications). A VM may execute guest software that uses an underlying emulation of the physical resources (e.g., virtual processors and guest memory).

In another embodiment, a virtual environment may be a container that may execute on a container engine which executes on top of the OS for a computing device, as discussed in more detail below. A container may be an isolated set of resources allocated to executing an application, software, and/or process independent from other applications, software, and/or processes. The host OS (e.g., an OS of the computing device) may use namespaces to isolate the resources of the containers from each other. A container may also be a virtualized object similar to virtual machines. However, a container may not implement separate guest OS (like a VM). The container may share the kernel, libraries, and binaries of the host OS with other containers that are executing on the computing device. The container engine may allow different containers to share the host OS (e.g., the OS kernel, binaries, libraries, etc.) of a computing device. The container engine may also facilitate interactions between the container and the resources of the computing device. The container engine may also be used to create, remove, and manage containers.

The storage resources 330 may include various different types of storage devices, such as hard disk drives (HDDs), solid state drives (SSD), hybrid drives, storage area networks, storage arrays, etc. The storage resources 330 may also include cloud storage resources or platforms which allow for dynamic scaling of storage space.

Although the computing resources 320 and the storage resources 330 are illustrated separate from the health monitoring system 310, one or more of the computing resources 320 and the storage resources 330 may be part of the health monitoring system 310 in other embodiments. For example, the health monitoring system 310 may include both the computing resources 320 and the storage resources 330.

As illustrated in FIG. 3, the health monitoring system 310 includes health module 350. In one embodiment, the health module 350 may perform functions, operations, actions, similar to health module 250 illustrated in FIG. 2. For example, health module 350 may determine, generate, calculate, etc., one or more capacity indicators for a portion of a battery (e.g., for battery cell groups).

As discussed above, although different portions of the battery may degrade or age differently, the health module 250 may be able to determine a capacity indicator for each of the different portions of the battery (e.g., for each battery cell group). By using one or more of storage capacities during charging events, voltages during charging events, and balancing operations that were performed, the health module 350 may be able to determine a capacity indicator for each portion of the battery (e.g., for each battery cell group).

FIG. 4 is a diagram illustrating an example battery module 400, in accordance with some embodiments of the present disclosure. As discussed, a power source (e.g., power source 110 illustrated in FIG. 1) for a device (e.g., vehicle 100 illustrated in FIG. 1) may be a battery (e.g., a lithium ion battery). The battery may divided into and/or composed of multiple battery modules, such as battery module 400. The battery may include any appropriate number of battery modules 400 (e.g., as many battery modules 400 as needed to provide a particular, current, voltage, power, energy, etc.).

As illustrated in FIG. 1, battery module 400 may include multiple battery cells 411 (e.g., lithium ion cells). A battery cell 411 may be a device or unit that generates electrical energy using one or more processes (e.g., via a chemical process, thermal process, etc.). Each battery cell 411 may include a cathode, an anode, and an electrolyte. The battery cells 411 may be grouped, organized, into battery cell groups 410. Each battery cell group 410 includes a set of battery cells 411 (e.g., one or more battery cells 411), a resistor 413, and a switch 415. The set of battery cells 411 are coupled in parallel along with the resistor 413. Any appropriate number of battery cells 411 may be included in a battery cell group 410 in other embodiments. A battery cell group 410 may be referred to as a lumped cell, a cell group, etc.

In one embodiment, the amount of stored energy in different battery cell groups 410 may not be uniform (e.g., may not be even, may not be uniformly distributed, may not be evenly distributed, etc.) across the battery cell groups 410. For example, after a charging event, some battery cell groups 410 may have more energy than other battery cell groups 410. This may be caused by various factors, parameters, conditions, criterion, etc. For example, the amount of stored energy in different battery cell groups 410 may not be uniform due to different aging of the battery cell groups 410, different temperatures of the battery cell groups 410 (e.g., some battery cell groups 410 may get hotter than others), manufacturing variations for the battery cell groups 410, etc.

If the amount of stored energy in the different battery cell groups 410 are not uniform, there may be issues, problems, etc., that may occur when charging the battery. For example, if current is provided to a battery cell group 410 that is already at a threshold capacity or maximum capacity, this may result in overcharging the battery cell group 410 and may damage that battery cell group 410 (e.g., may damage individual battery cells 411 and/or may degrade the health/capacity of the individual battery cells 411).

In one embodiment, balancing may be performed on and/or for one or more battery cell groups 410 to address these issues. Balancing may refer to controlling, adjusting, etc., the amount of current that is provided to a battery cell group 410. For example, the amount of current that is provided to a battery cell group 410 may be reduced to prevent a battery cell group 410 from overcharging. The amount of current provided to the battery cell group 410 may be controlled based on the switch 415 and the resistor 413. When balancing is performed, the switch 415 may be turned on to connect the resistor 413 to the other battery cells 411 (in the battery cell group 410) in parallel. The resistance of the resistor 413 may decrease the amount of current that is provided to the battery cells 411 (e.g., may slow down the flow of current to the battery cells 411).

In one embodiment, the balancing of the battery cell group 410 may be performed throughout a charging event. As the battery cell group 410 is charged (during the charging event), the battery management system may monitor characteristics, parameters, conditions, etc., of the battery cell group 410. For example, the battery management system may monitor the voltage of the battery cell group 410 (e.g., the overall voltage of all the battery cells 411 in the battery cell group 410). In another example, the battery management system may monitor the current state of charge of the battery cell group 410 (e.g., the overall state of charge of all the battery cells 411 in the battery cell group 410). In a further example, the battery management system may monitor the amount of current provide to a battery cell group 410. The battery management system may balance the battery cell group 410 (and other battery cell groups 410) multiple times (e.g., may perform multiple balancing operations, such as turning on/off switch 415 multiple times).

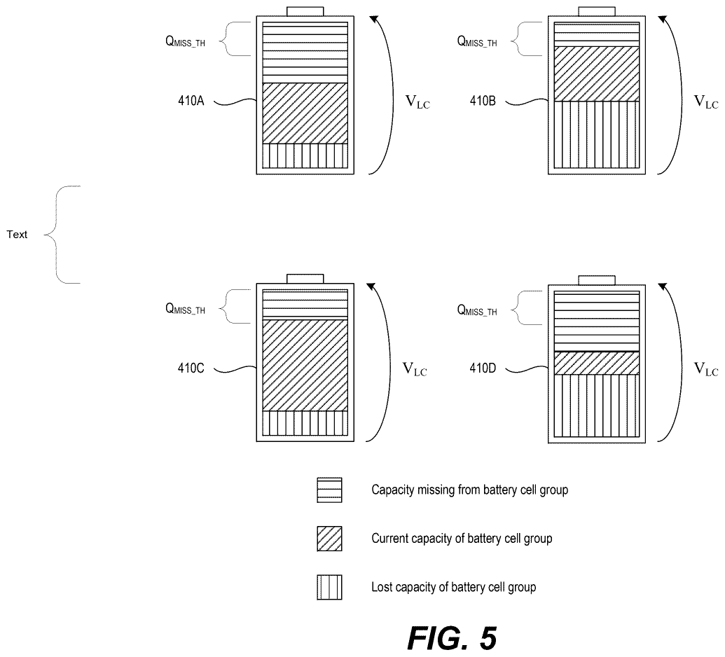

FIG. 5 is a block diagram illustrating example battery cell groups 410A, 410B, 410C, and 410D, in accordance with some embodiments of the present disclosure. As discussed above, a battery (e.g., power source 110 illustrated in FIG. 1) for a device (e.g., vehicle 100 illustrated in FIG. 1) may include multiple battery cell groups. Four such battery cell groups 410A, 410B, 410C, and 410D are represented in FIG. 5 (e.g., each battery cell group 410A, 410B, 410C, and 410D is represented with a single image/icon of a battery). The battery cell groups 410A, 410B, 410C, and 410D may each represent one battery cell group 410 illustrated in FIG. 4.

In particular, various capacities and/or voltages of the battery cell groups 410A, 410B, 410C, and 410D are illustrated in FIG. 5, rather than the specific components, devices, modules, circuits, etc., that may be in the battery cell groups 410A, 410B, 410C, and 410D. For example, the capacity missing from a battery cell group (e.g., the combined missing capacity of all the battery cells in the battery cell group), the current capacity of the battery cell group (e.g., the combined current capacity of all the battery cells in the battery cell group), and a lost capacity of a battery cell group (e.g., the combined lost capacity of all the battery cells in the battery cell group) are illustrated.

In one embodiment, the lost capacity of a battery cell group may represent the loss in the capacity of the battery cell group. For example, the lost capacity may indicate how much less energy a battery cell group can store compared to when the battery cell group was new (e.g., brand new). The lost capacity of a battery cell group may be due aging, degradation, etc., of the battery caused by charging and discharging the battery cell group.

As discussed above, balancing operations may be performed on the battery cell groups 410A, 410B, 410C, and 410D based on missing capacities and/or voltages of the battery cell groups 410A, 410B, 410C, and 410D. In one embodiment, the balancing (e.g., balancing operations) may be performed on a battery cell group based on a missing capacity for battery cell group. The missing capacity may represent, indicate, refer to, etc., a portion of the total capacity of the battery that is missing (or not filled/charged) after the charging event. For example, if the battery cell group is not fully charged after a charging event (e.g., is not at full capacity), the difference between the amount of energy stored at full capacity and the amount of energy at the current capacity of the battery cell group may be the missing capacity. The missing capacity may also refer to the amount of energy that is missing from the battery cell group (e.g., the amount of energy that can be charged or provided to the battery before the state of charge is 100%). The missing capacity may also be represented using the following equation:

$${Q}_{miss , j} ( t ) = \frac{{SOC}_{end} - {SOC}_{j} ( t )}{100} {Q}_{j} \qquad ( 2 )$$

Q_{miss,j}(t) may represent the missing capacity. Qⱼ may represent the total capacity (e.g., total energy capacity) of the battery cell group. SOC_{end} may represent the desired state of charge of the battery cell group at the end of the charging event (e.g., a desired state of charge of 100%, 90%, or some other appropriate state of charge). SOCⱼ(t) may represent the actual or measured state of charge of a particular battery cell group (e.g., one of battery cell groups 410A through 410D) at the end of the charging event.

In one embodiment, a balancing operation may be performed if the missing capacity of a battery cell group is less than a threshold missing capacity Q_{MISS_TH}. For example, as illustrated in FIG. 5, balancing operations based on the missing capacity may not be performed on battery cell groups 410A and 410D because the missing capacity is greater than (or equal to) the threshold missing capacity Q_{MISS_TH}. Balancing operations may be performed on battery cell groups 410B and 410C because the missing capacity is less than the threshold missing capacity Q_{MISS_TH}.

In one embodiment, the balancing (e.g., balancing operations) may also be performed on a battery cell group (e.g., one of battery cell groups 410A through 410D) based on a voltage of the battery cell group (e.g., the voltage during the charging event). As discussed above, the battery management system (e.g., voltage module 210 of battery management system 120 illustrated in FIG. 2) may measure, detect, sense, etc., the voltage of each battery cell group during a charging event. The voltage of a battery cell group may be referred to as V_{LC}. When V_{LC}>Vₘᵢₙ for a battery cell group, balancing operations may be performed for the battery cell group (e.g., the battery cell group may be balanced). Vₘᵢₙ may be a threshold voltage used to determine whether balancing operations should be performed. For example, Vₘᵢₙ may represent the minimum allowed (or desired) voltage measured among all the battery cell groups 410. If V_{LC}≤Vₘᵢₙ for battery cell group, balancing operations may not be performed for the battery cell group.

In one embodiment, balancing a battery cell group (e.g., one of battery cell groups 410A through 410D) based on a missing capacity for battery cell group and balancing the battery cell group based on a voltage of the battery cell group, may be performed at different phases (e.g., stages, time periods, cycles, etc.). For example, a charging event may include multiple phases. The battery cell group may be balanced based on the missing capacity of the battery cell group 410 in a first phase, and may be balanced based on the voltage of the battery cell group 410 in a second phase. In another example, the battery cell group may be balanced based on the voltage of the battery cell group in a first phase, and may be balanced based on the missing capacity of the battery cell group in a second phase. In addition, there may one or more intermediate phases between the phases where the battery cell group is balanced based on the missing capacity and balanced based on the voltage (e.g., one or more intermediate phases between the first phase and the second phase).

As discussed above, a capacity indicator may be determined for each of the battery cell groups 410A through 410D, based on the balancing operations that were performed on the battery cell groups 410A through 410D during a charging event. For example, if the battery cell group 410A was not balanced based on a missing capacity (e.g., was not balanced during a first phase) and was balanced based on a voltage (e.g., was balanced during a second phase), the battery cell group 410A may have a higher value capacity indicator. The higher value capacity indicator may indicate that the battery cell group 410A has a lower level of aging/degradation (has a smaller loss in capacity). In another example, if the battery cell group 410B was balanced based on a missing capacity (e.g., was balanced during a first phase) and was not balanced based on a voltage (e.g., was not balanced during a second phase), the battery cell group 410B may have a lower value capacity indicator. The lower value capacity indicator may indicate that the battery cell group 410B has a higher level of aging/degradation (has a larger loss in capacity). In a further example, if the battery cell group 410D was not balanced based on a missing capacity (e.g., was not balanced during a first phase) and was not balanced based on a voltage (e.g., was not balanced during a second phase), the battery cell group 410D may have a medium value capacity indicator. The medium value capacity indicator may indicate that the battery cell group 410D has a medium level of aging/degradation (has a medium loss in capacity that is between the higher value and the lower value).

In yet another example, if the battery cell group 410C was balanced based on a missing capacity (e.g., was balanced during a first phase) and was balanced based on a voltage (e.g., was balanced during a second phase), the battery cell group 410C may have a fourth capacity indicator. In one embodiment, the fourth capacity indicator may indicate that the battery cell group 410C has level of aging/degradation that is between the medium level and the higher level. In another embodiment, the fourth capacity indicator may indicate that the battery cell group 410C has level of aging/degradation that is between the medium level and the lower level. In a further embodiment, the fourth capacity indicator may indicate that the battery cell group 410C has level of aging/degradation even lower than the lower level. In yet another embodiment, the fourth capacity indicator may indicate that the battery cell group 410C has level of aging/degradation even higher than the higher level.

In one embodiment, a high/higher value capacity indicator may correspond to a first range of capacities. For example, a high/higher value capacity indicator may indicate that a battery cell group has a first threshold percentage of its original capacity (e.g., 90%, 85%, or some other appropriate percentage). A low/lower value capacity indicator may indicate that a battery cell group has a second threshold percentage of its original capacity (e.g., 35%, 25%, or some other appropriate percentage). A medium value capacity indicator may indicate the battery cell group has a capacity between the first threshold percentage and the second threshold percentage.

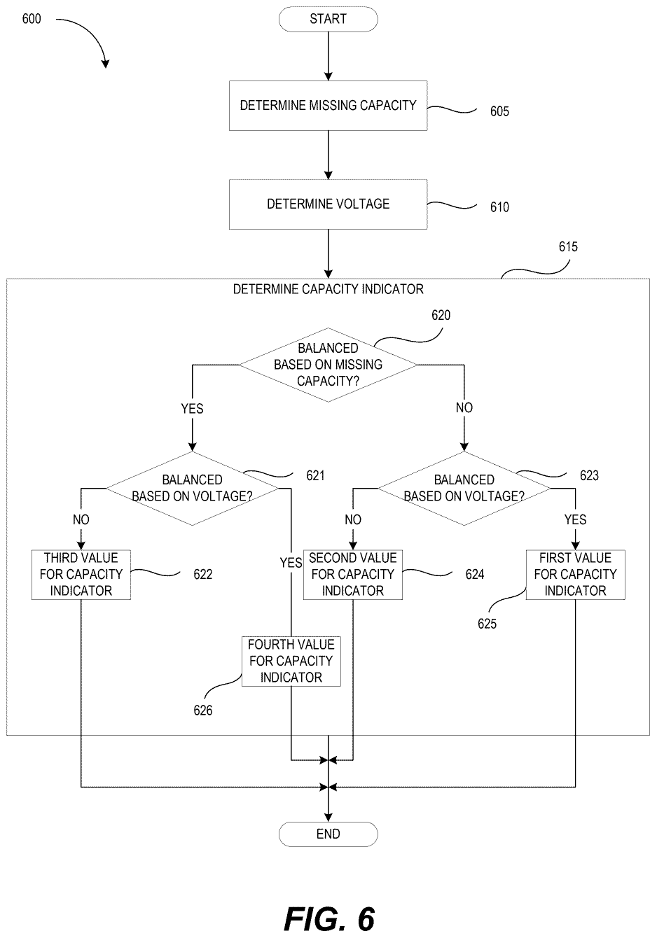

FIG. 6 is a flow diagram of a method 600 for determining a capacity indicator, in accordance with one or more embodiments of the present disclosure. Method 600 may be performed by processing logic that may comprise hardware (e.g., circuitry, dedicated logic, programmable logic, a field programmable gate array (FPGA), an application specific integrated circuit (ASIC), a processor, a processing device, a central processing unit (CPU), a system-on-chip (SoC), etc.), software (e.g., instructions running/executing on a processing device), firmware (e.g., microcode), or a combination thereof. In some embodiments, the method 600 may be performed by a computing device (e.g., a server computer, a desktop computer, etc.), a health module (e.g., health module 250/350 illustrated in FIGS. 2-3), a battery management system (e.g., battery management system 120 illustrated in FIGS. 1-2), and/or various components, modules, systems, etc., of the battery management system (as illustrated in FIG. 2).

With reference to FIG. 6, method 600 illustrates example functions used by various embodiments. Although specific function blocks (“blocks”) are disclosed in method 600, such blocks are examples. That is, embodiments are well suited to performing various other blocks or variations of the blocks recited in method 600. It is appreciated that the blocks in method 600 may be performed in an order different than presented, and that not all of the blocks in method 600 may be performed, and other blocks (which may not be included in FIG. 6) may be performed between the blocks illustrated in FIG. 6.

The method 600 begins at block 605 where the method 600 may determine a missing capacity of a battery cell group (e.g., battery cell group 410 illustrated in FIG. 4). For example, the method 600 may use equation (2) to determine, calculate, etc., the missing capacity of the battery cell group during a charging event. At block 610, the method 600 may determine the voltage of the battery cell group. For example, the method 600 may measure the voltage of the battery during the charging event. At block 615 the method 600 may determine (e.g., calculate, generate, etc.) a capacity indicator for the battery cell group. In particular, the method 600 may perform one or more of blocks 621 through 626 to determine the capacity indicator of the battery cell group.

At block 620, the method 600 may determine whether the battery cell group was balanced based on a missing capacity of the battery cell group. If the battery cell group was not balanced based on the missing capacity of the battery cell group, the method 600 may proceed to block 623, where the method 600 determines whether the battery cell group was balanced based on the voltage of the battery cell group. If the battery cell group was balanced based on the voltage, the method 600 may determine, assign, use, etc., a first value for the capacity indicator. As discussed above, the first value may indicate a lower loss in the capacity of the battery cell group (e.g., the battery cell has a high capacity). If the battery cell group was not balanced based on the voltage, the method 600 may determine, assign, use, etc., a second value for the capacity indicator at block 624. As discussed above, the second value may indicate a medium loss in the capacity of the battery cell group (e.g., the battery cell has a medium capacity).

If the battery cell group was balanced based on the missing capacity of the battery cell group, the method 600 may proceed to block 621, where the method 600 determines whether the battery cell group was balanced based on the voltage of the battery cell group. If the battery cell group was not balanced based on the voltage, the method 600 may determine, assign, use, etc., a third value for the capacity indicator at block 622. As discussed above, the third value may indicate a higher loss in the capacity of the battery cell group (e.g., the battery cell has a low capacity). If the battery cell group not balanced based on the voltage, the method 600 may determine, assign, use, etc., a fourth value for the capacity indicator at block 626.

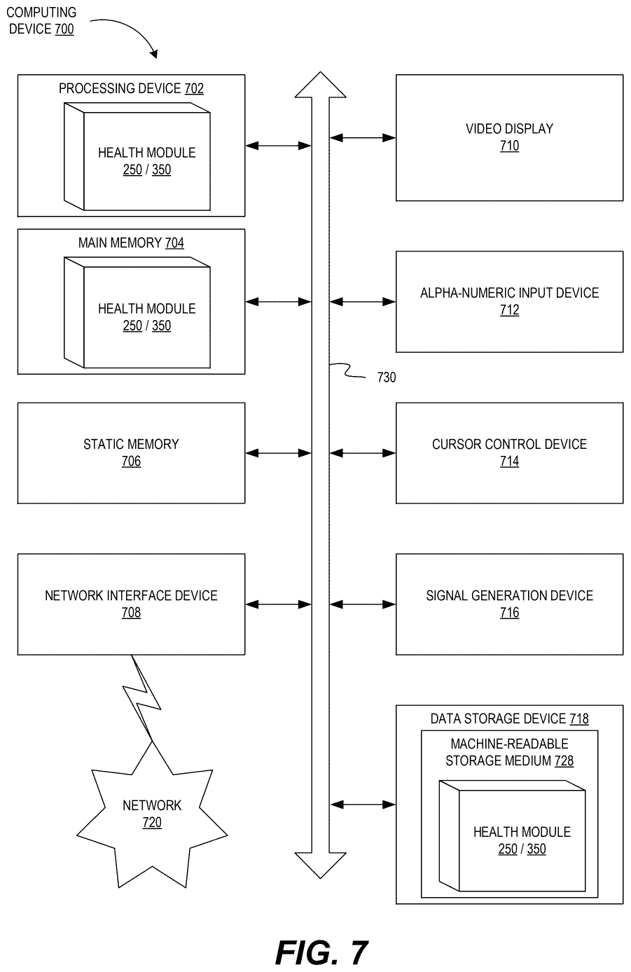

FIG. 7 is a block diagram of an example computing device 700 that may perform one or more of the operations described herein, in accordance with some embodiments. Computing device 700 may be connected to other computing devices in a LAN, an intranet, an extranet, and/or the Internet. The computing device may operate in the capacity of a server machine in client-server network environment or in the capacity of a client in a peer-to-peer network environment. The computing device may be provided by a personal computer (PC), a set-top box (STB), a server, a network router, switch or bridge, or any machine capable of executing a set of instructions (sequential or otherwise) that specify actions to be taken by that machine. Further, while only a single computing device is illustrated, the term “computing device” shall also be taken to include any collection of computing devices that individually or jointly execute a set (or multiple sets) of instructions to perform the methods discussed herein.

The example computing device 700 may include a processing device 702 (e.g., a general purpose processor, a PLD, etc.), a main memory 704 (e.g., synchronous dynamic random access memory (DRAM), read-only memory (ROM)), a static memory 706 (e.g., flash memory and a data storage device 718), which may communicate with each other via a bus 730.

Processing device 702 may be provided by one or more general-purpose processing devices such as a microprocessor, central processing unit, or the like. In an illustrative example, processing device 702 may comprise a complex instruction set computing (CISC) microprocessor, reduced instruction set computing (RISC) microprocessor, very long instruction word (VLIW) microprocessor, or a processor implementing other instruction sets or processors implementing a combination of instruction sets. Processing device 702 may also comprise one or more special-purpose processing devices such as an application specific integrated circuit (ASIC), a field programmable gate array (FPGA), a digital signal processor (DSP), network processor, or the like. The processing device 702 may be configured to execute the operations described herein, in accordance with one or more aspects of the present disclosure, for performing the operations and steps discussed herein.

Computing device 700 may further include a network interface device 708 which may communicate with a network 720. The computing device 700 also may include a video display unit 710 (e.g., a liquid crystal display (LCD) or a cathode ray tube (CRT)), an alphanumeric input device 712 (e.g., a keyboard), a cursor control device 714 (e.g., a mouse) and an acoustic signal generation device 716 (e.g., a speaker). In one embodiment, video display unit 710, alphanumeric input device 712, and cursor control device 714 may be combined into a single component or device (e.g., an LCD touch screen).

Data storage device 718 may include a computer-readable storage medium 728 on which may be stored one or more sets of instructions, e.g., instructions for carrying out the operations described herein, in accordance with one or more aspects of the present disclosure. Instructions implementing the different systems described herein (e.g., health module 250, health module 350, battery management system 120 and/or various components, modules, systems, etc., as illustrated in FIGS. 1-3) may also reside, completely or at least partially, within main memory 704 and/or within processing device 702 during execution thereof by computing device 700, main memory 704 and processing device 702 also constituting computer-readable media. The instructions may further be transmitted or received over a network 720 via network interface device 708.

While computer-readable storage medium 728 is shown in an illustrative example to be a single medium, the term “computer-readable storage medium” should be taken to include a single medium or multiple media (e.g., a centralized or distributed database and/or associated caches and servers) that store the one or more sets of instructions. The term “computer-readable storage medium” shall also be taken to include any medium that is capable of storing, encoding or carrying a set of instructions for execution by the machine and that cause the machine to perform the methods described herein. The term “computer-readable storage medium” shall accordingly be taken to include, but not be limited to, solid-state memories, optical media and magnetic media.

Unless specifically stated otherwise, terms such as “generating,” “determining,” “coupling,” “identifying,” “providing,” “measuring,” “adjusting,” “dividing,” “requesting,” “providing,” or the like, refer to actions and processes performed or implemented by computing devices that manipulates and transforms data represented as physical (electronic) quantities within the computing device's registers and memories into other data similarly represented as physical quantities within the computing device memories or registers or other such information storage, transmission or display devices. Also, the terms “first,” “second,” “third,” “fourth,” etc., as used herein are meant as labels to distinguish among different elements and may not necessarily have an ordinal meaning according to their numerical designation.

Examples described herein also relate to an apparatus for performing the operations described herein. This apparatus may be specially constructed for the required purposes, or it may comprise a general purpose computing device selectively programmed by a computer program stored in the computing device. Such a computer program may be stored in a computer-readable non-transitory storage medium.

The methods and illustrative examples described herein are not inherently related to any particular computer or other apparatus. Various general purpose systems may be used in accordance with the teachings described herein, or it may prove convenient to construct more specialized apparatus to perform the required method steps. The required structure for a variety of these systems will appear as set forth in the description above.

The above description is intended to be illustrative, and not restrictive. Although the present disclosure has been described with references to specific illustrative examples, it will be recognized that the present disclosure is not limited to the examples described. The scope of the disclosure should be determined with reference to the following claims, along with the full scope of equivalents to which the claims are entitled.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. A method, comprising:
determining a missing capacity for a battery cell group during a charging event, wherein the missing capacity indicates a difference between a first amount of energy stored at a full capacity of the battery cell group and a second amount of stored at a current capacity of the battery cell group;
determining a voltage of the battery cell group during the charging event; and
determining a capacity indicator of the battery cell group based on whether balancing was performed based on one or more of the missing capacity and the voltage.

2. The method of claim 1, wherein balancing is performed on the battery cell group based on the missing capacity during a first phase of the charging event and balancing is performed based on the voltage of the battery cell group during a second phase of the charging event.

3. The method of claim 1, wherein performing balancing on the battery cell group comprises:
coupling a resistor in parallel with the battery cell group, wherein an amount of current flowing to the battery cell group is reduced when the resistor is coupled in parallel.

4. The method of claim 1, further comprising:
determining whether the missing capacity is less than a threshold missing capacity; and
in response to determining that the missing capacity is less than the threshold missing capacity, balancing the battery cell group.

5. The method of claim 1, further comprising:
determining whether the voltage of the battery cell group is greater than a voltage threshold; and
in response to determining the voltage of the battery cell group is greater than the voltage threshold, balancing the battery cell group.

6. The method of claim 1, wherein determining the capacity indicator of the battery cell group comprises:
determining capacity indicator of the battery cell group is at a first capacity indicator when balancing is not performed on the battery cell group based on the missing capacity and when balancing is performed on the battery cell group based on the voltage.

7. The method of claim 1, wherein determining the capacity indicator of the battery cell group comprises:
determining capacity indicator of the battery cell group is at a second capacity indicator when balancing is not performed on the battery cell group based on the missing capacity and when balancing is not performed on the battery cell group based on the voltage.

8. The method of claim 1, wherein determining the capacity indicator of the battery cell group comprises:
determining capacity indicator of the battery cell group is at a third capacity indicator when balancing is performed on the battery cell group based on the missing capacity and when balancing is not performed on the battery cell group based on the voltage.

9. The method of claim 1, wherein determining the missing capacity comprises:
determining a state of charge of the battery cell group; and
determining the missing capacity based on the state of charge and an original capacity of the battery cell group.

10. The method of claim 1, further comprising:
providing an indication of the capacity indicator to one or more of an interface system or a vehicle.

11. An apparatus, comprising:
a memory configured to store data; and
a processing device operatively coupled to the memory, the processing device configured to:
determine a missing capacity for a battery cell group during a charging event, wherein the missing capacity indicates a difference between a first amount of energy stored at a full capacity of the battery cell group and a second amount of stored at a current capacity of the battery cell group;
determine a voltage of the battery cell group during the charging event; and
determine a capacity indicator of the battery cell group based on whether balancing was performed based on one or more of the missing capacity and the voltage.

12. The apparatus of claim 11, wherein balancing is performed on the battery cell group based on the missing capacity during a first phase of the charging event and balancing is performed based on the voltage of the battery cell group during a second phase of the charging event.

13. The apparatus of claim 11, wherein to perform balancing on the battery cell group the processing device is further configured to:
couple a resistor in parallel with the battery cell group, wherein an amount of current flowing to the battery cell group is reduced when the resistor is coupled in parallel.

14. The apparatus of claim 11, wherein the processing device is further configured to:
determine whether the missing capacity is less than a threshold missing capacity; and
in response to determining that the missing capacity is less than the threshold missing capacity, balance the battery cell group.

15. The apparatus of claim 11, wherein the processing device is further configured to:
determine whether the voltage of the battery cell group is greater than a voltage threshold; and
in response to determining the voltage of the battery cell group is greater than the voltage threshold, balance the battery cell group.

16. The apparatus of claim 11, wherein to determine the capacity indicator of the battery cell group the processing device is further configured to:
determine capacity indicator of the battery cell group is at a first capacity indicator when balancing is not performed on the battery cell group based on the missing capacity and when balancing is performed on the battery cell group based on the voltage.

17. The apparatus of claim 11, wherein to determine the capacity indicator of the battery cell group the processing device is further configured to:
determine capacity indicator of the battery cell group is at a second capacity indicator when balancing is not performed on the battery cell group based on the missing capacity and when balancing is not performed on the battery cell group based on the voltage.

18. The apparatus of claim 11, wherein to determine the capacity indicator of the battery cell group the processing device is further configured to:
determine capacity indicator of the battery cell group is at a third capacity indicator when balancing is performed on the battery cell group based on the missing capacity and when balancing is not performed on the battery cell group based on the voltage.

19. The apparatus of claim 11, wherein to determine the missing capacity the processing device is further configured to:
determine a state of charge of the battery cell group; and
determine the missing capacity based on the state of charge and an original capacity of the battery cell group.

20. A non-transitory computer-readable storage medium including instructions that, when executed by a processing device, cause the processing device to:
determine a missing capacity for a battery cell group during a charging event, wherein the missing capacity indicates a difference between a first amount of energy stored at a full capacity of the battery cell group and a second amount of stored at a current capacity of the battery cell group;
determine a voltage of the battery cell group during the charging event; and
determine a capacity indicator of the battery cell group based on whether balancing was performed based on one or more of the missing capacity and the voltage.
